(19) United States
(12) Patent Application Publication
(10) Pub. No.: US 2019/0078740 A1
(43) Pub. Date: Mar. 14, 2019

(54) LED LIGHT MANUFACTURING METHOD OF DPM STYLE AND APPARATUS THEREOF

(71) Applicant: STC LIGHTING CORPORATION CO., LTD., Hwaseong-si, Gyeonggi-do (KR)

(72) Inventor: Yong Chul KIM, Suwon-si (KR)

(21) Appl. No.: 16/084,654

(22) PCT Filed: Oct. 27, 2016
(86) PCT No.: PCT/KR2016/012153

§ 371 Date: Sep. 13, 2018

(30) Foreign Application Priority Data
Mar. 30, 2016 (KR) 10-2016-0038730

(51) Int. Cl. F21K 9/90; H05K 3/12; F21V 29/70; F21V 23/00; H01L 33/64

(52) U.S. Cl. CPC F21K 9/90; H05K 3/1283; F21Y 2115/10; F21V 23/001; H01L 33/642; F21V 29/70

(57) ABSTRACT

An LED light manufacturing method includes a step of printing an insulation paste containing a glass frit on top of a heat dissipation base, a step of firing at high temperature after printing, a step of printing an electrical circuit pattern using a conductive paste containing a silver powder on top of the insulation layer after firing, a step of firing the heat dissipation base printed with the electrical circuit pattern above at high temperature, a step of printing and hardening a protective solder resist (SR) paste on top of the electrical circuit pattern above after firing, a step of mounting multiple LEDs and a power connector onto the surface after hardening, an a step of connecting a power cable including a waterproof wire rubber to a power connector and attaching a waterproof rubber gasket to a lens.

### BACKGROUND OF THE INVENTION

### 1. Field of the Invention

This invention relates to the manufacture of an LED light by directly forming an insulation layer and electrical circuit pattern and mounting an LED on a heat dissipation base with excellent heat dissipation characteristics. In general, LED lamps are characterized by the manufacture of a PCB substrate, which is mounted with an LED. The above method of using a PCB substrate involves a complicated, eco-unfriendly process because it requires processes like exposure, etching and cleaning. Accordingly, this invention relates to an eco-friendly LED manufacturing method that introduces a method of directly printing on a heat dissipation base.

### 2. Description of Related Art

The conventional art related to this invention is Korean patent no. 10-1317236 (published on Oct. 15, 2013) applied and registered by the applicant of this invention. FIG. 1 is a flowchart of the conventional LED module manufacturing method of DPM (Direct Pattern Method) style using a heat dissipation base made of an insulation material. In FIG. 1, the conventional LED module manufacturing method of DPM style using a heat dissipation base made of an insulation material is characterized by a step (S21) of printing an electrical circuit pattern using a conductive ink on top of the heat dissipation base made of PBT (Polybutylene Terephthalate), PPS (Polyphenylene Sulfide), PET (Polyethylene Terephthalate), PC (Polycarbonate), PEN (Polybutylene Naphthalate) or POM (Polyoxymethylene) insulation material, a step (S22) of printing a PSR ink on top of the printed circuit pattern, a step (S23) of printing a cream solder on the soldering part of the printed circuit pattern, a step (S24) of automatically mounting LED chips on the cream solder printing part, and a step of heating the cream solder and soldering the LED chip after mounting of the LED chip.

### SUMMARY OF THE INVENTION

The conventional LED module manufacturing method of DPM style using a heat dissipation base made of an insulation material prints an electrical circuit pattern directly on the heat dissipation base, but there is a problem of slow heat dissipation due to poor heat dissipation characteristics of most insulation materials. Also, the conventional art is difficult to be used as an outdoor light due to the lack of waterproof ability. This LED module has a short life span because of gaps formed during manufacture. Accordingly, the purpose of this invention is to introduce an eco-friendly method of manufacturing an LED light and an apparatus thereof, with a long life span and strong waterproof.

The LED light manufacturing method of this invention with the purpose described above is characterized by a step of printing an insulation paste containing a glass frit on top of a heat dissipation base, a step of firing at high temperature after printing, a step of printing an electrical circuit pattern using a conductive paste containing a silver powder on top of the insulation layer after firing, a step of firing the heat dissipation base printed with the electrical circuit pattern above at high temperature, a step of printing and hardening a protective SR (Solder Resist) paste on top of the electrical circuit pattern above after firing, a step of mounting multiple LEDs and a power connector onto the surface after hardening, an a step of connecting a power cable including a waterproof wire rubber to a power connector and attaching a waterproof rubber gasket to a lens.

### Advantageous Effects

Since the LED light manufacturing method above does not involve etching and cleaning processes, it can prevent generation of environmental wastes. Another effect of this invention is to reduce the defect rate in the manufacturing process, which is simple without exposure, etching and cleaning processes. Another effect of this invention is to show excellent heat dissipation characteristics and extend the life span because of slim layers and no gaps between layers. Another effect of this invention is to show excellent linear resistance and adhesion because of sintering the layers into one body through high temperature firing. This invention can be applied to outdoor uses because of a waterproof structure.

### BRIEF DESCRIPTION OF THE DRAWINGS

FIG. 1 is a flowchart of the conventional LED module manufacturing method of DPM (Direct Pattern Method) style using a heat dissipation base made of an insulation material.

FIG. 2 is a flowchart of the LED light manufacturing method of DPM style according to this invention.

FIG. 3 is a block diagram of the heat dissipation base applied to this invention.

FIG. 4 is a block diagram of the heat dissipation base printed with the insulation layer.

FIG. 5 is a block diagram of the insulation layer printed with the electrical circuit pattern.

FIG. 6 is a block diagram of the electrical circuit pattern printed with the protective SR paste.

FIG. 7 is a block diagram of the protective SR paste printed with a silk layer.

FIG. 8 is a block diagram of the silk layer mounted with the LEDs and power connector.

FIG. 9 is a block diagram of the heat dissipation base inserted with the waterproof wire rubber through the central hole, where the waterproof wire is connected to the power connector.

FIG. 10 is a block diagram of the heat dissipation base connected with the waterproof rubber gasket and cover attached with the lens.

FIG. 11 is an exploded perspective view of the LED apparatus manufacturing using the DPM manufacturing method of this invention.

FIG. 12 is a photo showing the final LED apparatus of this invention.

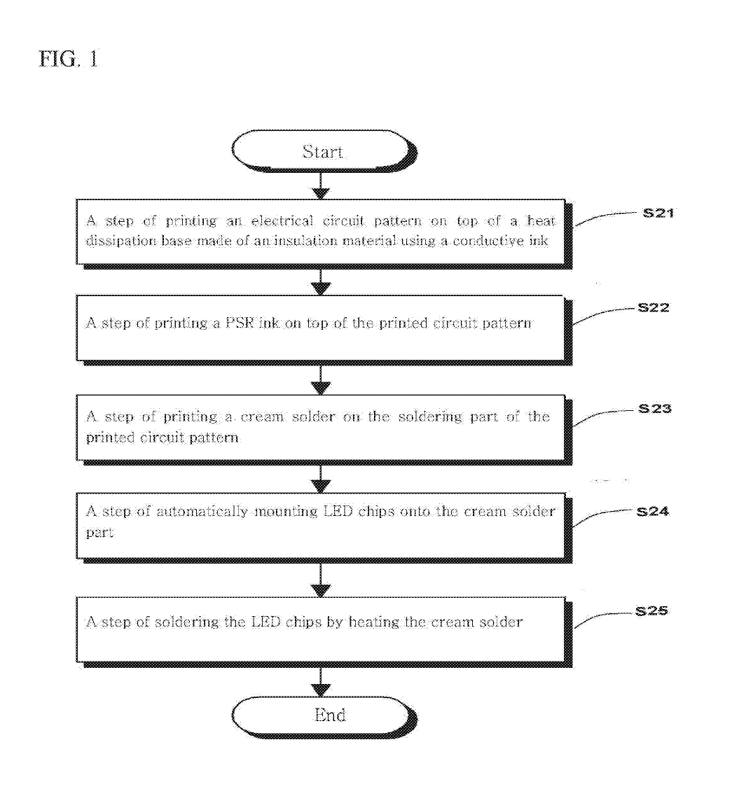

### DETAILED DESCRIPTION OF THE INVENTION

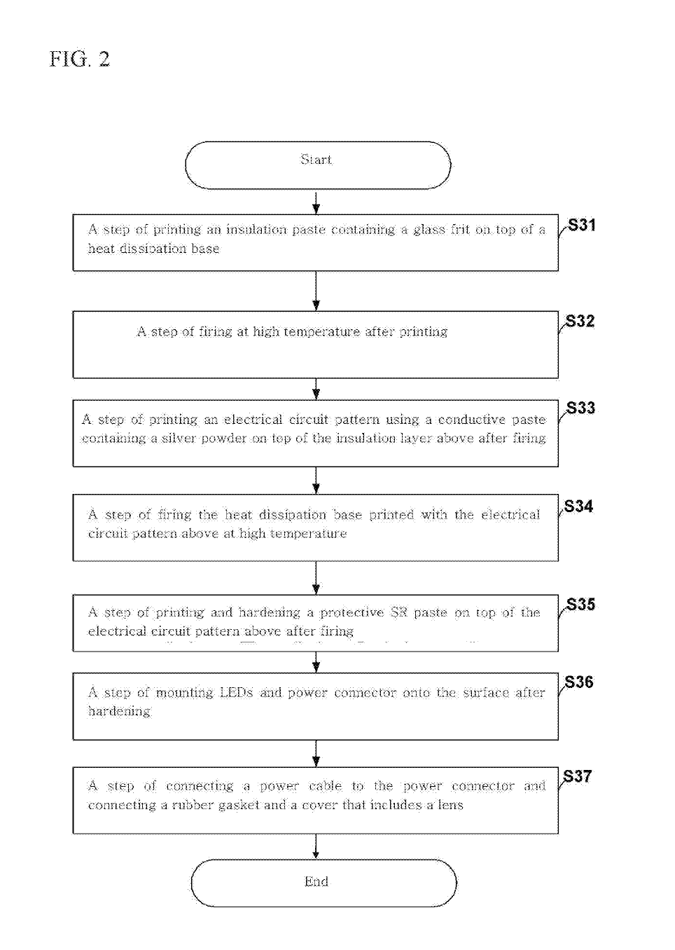

The LED light manufacturing method of DPM style and the apparatus thereof according to this invention can be described as below using FIGS. 2 through 12.

FIG. 2 is a flowchart of the LED light manufacturing method of DPM style according to this invention. In FIG. 2, the DPM-style LED light manufacturing method of this invention is characterized by a step (S31) of printing an insulation paste containing a glass frit on top of a heat dissipation base, a step (S32) of firing at high temperature after printing, a step (S33) of printing an electrical circuit pattern using a conductive paste containing a silver powder on top of the insulation layer above after firing, a step (S34) of firing the heat dissipation base printed with the electrical circuit pattern above at high temperature, a step (S35) of printing and hardening a protective SR (Solder Resist) paste on top of the electrical circuit pattern above after firing, a step (S36) of mounting multiple LEDs and a power connector after hardening, and a step (S37) of connecting a power cable to the power connector and connecting a waterproof rubber gasket and a cover that includes a lens. In the steps above, the step (S31) of printing the insulation paste containing the glass frit on top of the heat dissipation base is characterized by repeated printing and firing of the insulation paste containing the glass frit within the thickness range of 80 μm ˜100 μm. The step (S32) of firing at high temperature after printing is characterized by firing at high temperature of 500° C.-600° C. The step (S33) of printing the electrical circuit pattern using the conductive paste containing the silver powder on top of the insulation layer above after firing is characterized by repeated printing and firing of the electrical circuit pattern using the conductive paste containing the silver powder within the thickness range of 30 μm˜40 μm. The step (S34) of firing the heat dissipation base printed with the electrical circuit pattern above at high temperature is characterized by firing at high temperature of 450° C.˜550° C. The step (S35) of printing and hardening the protective SR paste on top of the electrical circuit pattern above is characterized by hardening of the paste at high temperature of 200° C.˜300° C. for 10 ˜30 minutes.

FIG. 3 is a block diagram of the heat dissipation base applied to this invention. In FIG. 3, the heat dissipation base applied to this invention represents a heat dissipation base (10) with a comb-patterned heat sink (11) on the back, a hole (13) at the center, and a body part (17) formed with multiple bolt holes (15). The central hole (13) formed on top of the body part above (17) is inserted with the waterproof wire rubber. The cover attached with the lens is connected to the multiple bolt holes (15). Also, the heat dissipation base above can be manufacturing using an aluminum or magnesium alloy ceramic material.

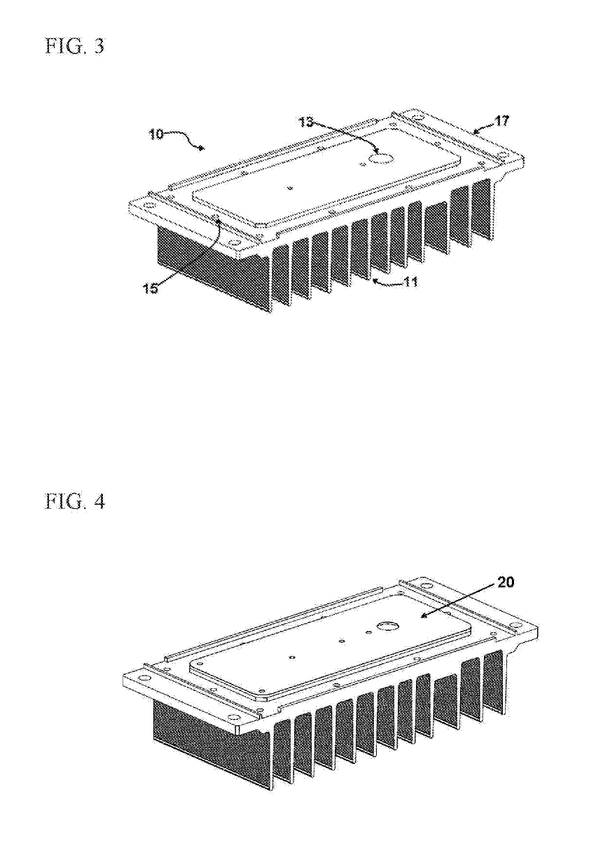

FIG. 4 is a block diagram of the heat dissipation base printed with the insulation layer. In FIG. 4, the insulation layer (2) printed on the heat dissipation base applied to this invention represents printing of the conductive paste containing the glass frit on top of the heat dissipation base by firing at high temperature.

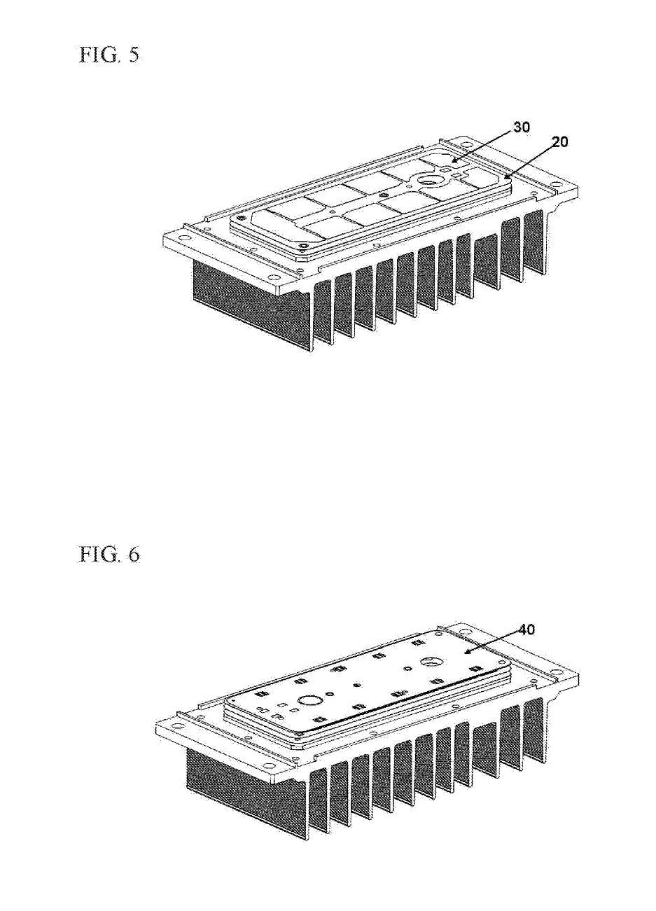

FIG. 5 is a block diagram of the insulation layer printed with the electrical circuit pattern. In FIG. 5, the electrical circuit pattern (3) printed on top of the insulation layer represents printing done by firing the conductive paste containing the silver powder at high temperature.

FIG. 6 is a block diagram of the electrical circuit pattern printed with the protective SR paste. In FIG. 6, the protective SR layer (40) printed on top of the electrical circuit pattern is formed by printing the protective SR paste and hardening the paste at high temperature.

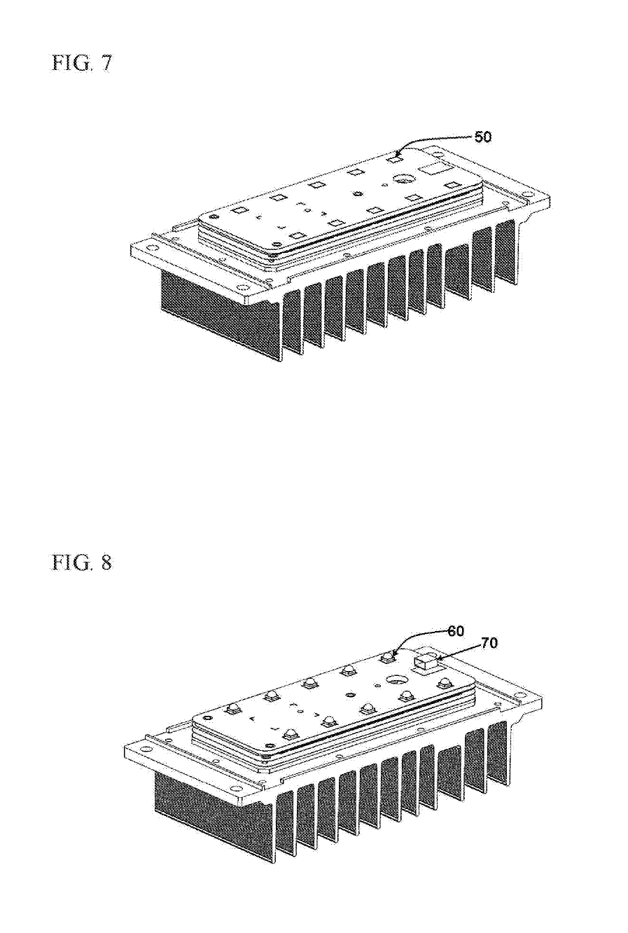

FIG. 7 is a block diagram of the protective SR paste printed with a silk layer. In FIG. 7, the silk layer (50) printed on top of the protective SR paste is formed by printing the silk layer and hardening it at high temperature.

FIG. 8 is a block diagram of the silk layer mounted with the LEDs and power connector. In FIG. 8, mounting of the LEDs (60) and power connector (70) after silk printing is done by printing the cream solder on the soldering part of the heat dissipation base with the electrical circuit pattern, mounting the LEDs and power connector onto the surface, melting the cream solder by heating, and soldering the LEDs and power connector. In the soldering part above, the protective SR paste is printed on top of the electrical circuit pattern layer. It represents the part where the SR paste is not printed on the electrical pattern layer.

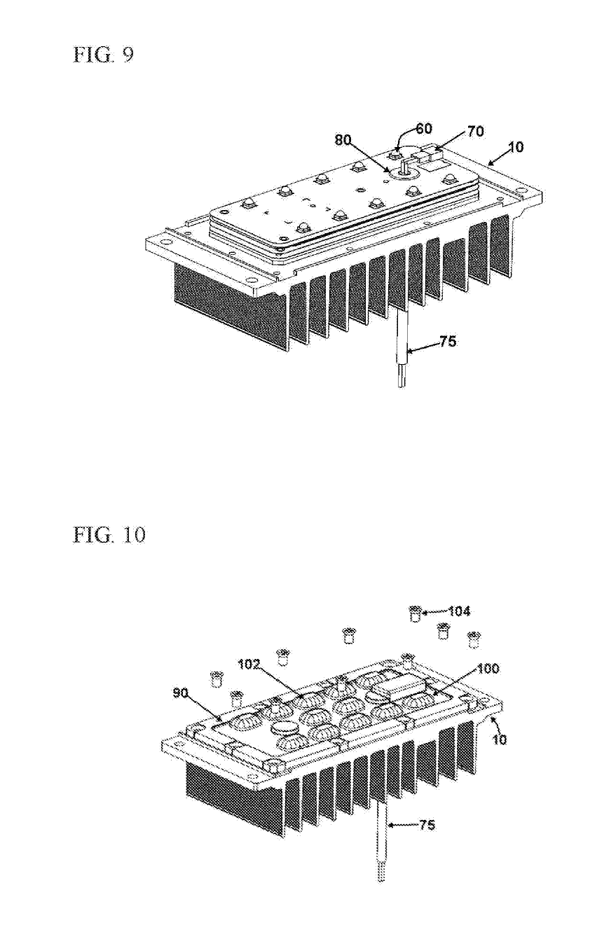

FIG. 9 is a block diagram of the heat dissipation base inserted with the waterproof wire rubber (80) through the central hole (13), where the waterproof wire is connected to the power connector. In FIG. 9, the waterproof wire rubber is inserted into the central hole formed on the heat dissipation base and the waterproof wire (75) is connected to the power connector (70) through the central hole above.

FIG. 10 is a block diagram of the heat dissipation base connected with the waterproof rubber gasket and cover attached with the lens. In FIG. 10, the heat dissipation base (10) is connected with the waterproof rubber gasket (90) on the top border for waterproof. The cover (100) attached with the lens (102) forming a specific angle to reflect light at a specific angle is connected to each LED using bolts (104).

FIG. 11 is an exploded perspective view of the LED apparatus manufacturing using the DPM manufacturing method of this invention. In FIG. 11, the LED apparatus manufacturing using the DPM-style manufacturing method of this invention is comprised of the body part (17) formed with the central hole and many bolt holes, the heat dissipation base (10) attached with the comb-patterned heat sink on the back, the insulation layer (20) printed on top of the heat dissipation base, the electrical circuit pattern layer (30) printed on top of the insulation layer, the protectivae SR layer (40) printed on top of the electrical circuit pattern layer, the silk layer (50) printed on top of the protective SR layer, the LEDs (60) and power connector (70) mounted on top of the silk layer above for electrical conduction with the electrical circuit pattern layer above, the waterproof power wire (75) connected to the power connector, the waterproof rubber gasket (90) connected to the border of the heat dissipation base above, and the cover (100) attached with the lens (102) connected to the LEDs above.

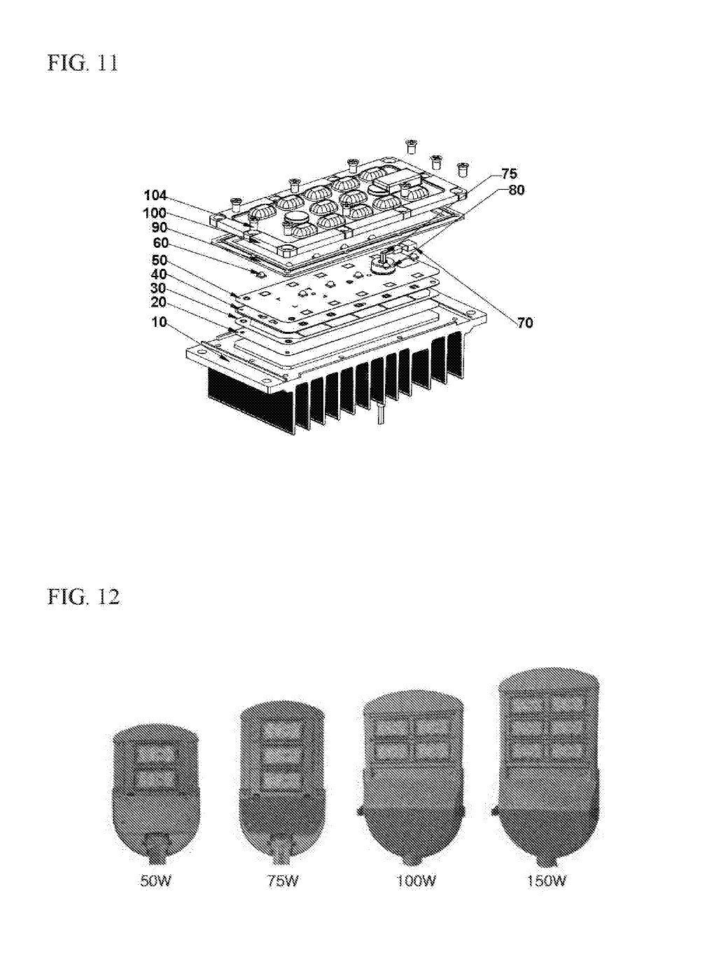

FIG. 12 is a photo showing the final LED apparatus of this invention. In FIG. 12, the LED apparatus manufacturing using the manufacturing method of this invention has a structure in which LED modules are installed inside frames of different shapes.

### INDUSTRIAL APPLICABILITY

The LED apparatus manufacturing by the process described above can minimize environmental wastes generated during manufacture and can be useful at industrial sites because of excellent heat dissipation and waterproof effects.

1. A method for manufacturing a light-emitting diode (LED) light of a direct pattern method (DPM) type based on a high temperature firing, the method comprising:
a step (31) of printing an insulation paste containing a glass frit on top of a heat dissipation base;
a step (S32) of firing at a high temperature after printing;
a step (S33) of printing an electrical circuit pattern using a conductive paste containing a silver powder on top of the insulation layer after firing;
a step (S34) of firing the heat dissipation base printed with the electrical circuit pattern at a high temperature;
a step (S35) of printing and hardening a protective solder resist (SR) paste on top of the electrical circuit pattern after firing
a step (S36) of mounting multiple LEDs and a power connector after hardening; and
a step (S37) of connecting a power cable to the power connector and connecting a waterproof rubber gasket and a cover that includes a lens.

2. The method of claim 1, wherein the step (S31) includes repeated printing and firing of the insulation paste containing the glass frit within a thickness range of 80 μm-100 μm.

3. The method of claim 1, wherein the step (S32) includes firing at a high temperature of 500° C.-600° C.

4. The method of claim 1, wherein the step (S33) includes repeated printing and firing of the electrical circuit pattern using the conductive paste containing the silver powder within a thickness range of 30 μm-40 μm.

5. The method of claim 1, wherein the step (S34) includes firing at a high temperature of 450° C.-550° C.

6. The method of claim 1, wherein the step (S35) includes hardening of the paste at a high temperature of 200° C.-300° C. for 10-30 minutes.

7. A light-emitting diode (LED) light of a direct pattern method (DPM) type based on a high temperature firing, comprising:
a heat dissipation base (10);
an insulation layer (20) printed on top of the heat dissipation base;
an electrical pattern layer (30) printed on top of the insulation layer,
a protective SR paste layer (40) printed on top of the electrical circuit pattern layer,
a silk layer (50) printed on top of the protective SR paste;
LEDs (60) and power connector (70) mounted for electrical conduction with the electrical circuit pattern layer on top of the silk layer;
a power wire (75) connected to the power connector and inserted through the central hole of the heat dissipation base;
a rubber gasket (90) connected to the border of the heat dissipation base; and
a cover (100) attached with a lens (102) connected to the top of each LED.

8. The LED light of claim 7, wherein the heat dissipation base includes a comb-patterned heat sink (11) on the back, a hole (13) at the center, and a body part (17) formed with multiple bolt holes (15).

9. The LED light of claim 7, wherein the rubber gasket (90) and the power wire (75) are waterproof, and a waterproof wire rubber (80) is inserted into the central hole.
